(19) United States
(12) Patent Application Publication
(10) Pub. No.: US 2004/0091811 A1
(43) Pub. Date: May 13, 2004

(54) Hetero-substituted aryl acetic acid co-initiators for IR-sensitive compositions

(76) Inventors: Heidi M. Munnelly, Windsor, CO (US); Paul R. West, Fort Collins, CO (US); Hans-Joachim Timpe, Osterode (DE); Ursula Muller, Harz (DE); Jianbing Huang, Trumbull, CT (US)

Correspondence Address: FAEGRE & BENSON LLP, 2200 WELLS FARGO CENTER, 90 SOUTH 7TH STREET, MINNEAPOLIS, MN, 55402, US

(21) Appl. No.: 10/283,757

(22) Filed: Oct. 30, 2002

(51) Int. Cl. G03F 7/038; G03F 7/11

(52) U.S. Cl. 430/270.1; 430/273.1; 430/281.1; 430/286.1; 430/302; 430/309; 430/434; 430/494; 430/944; 430/945

(57) ABSTRACT

An IR-sensitive composition comprising, in addition to a polymeric binder, a free radical polymerizable system consisting of at least one member selected from unsaturated free radical polymerizable monomers, oligomers which are free radical polymerizable, and polymers containing C═C bonds in the back bone and/or in the side chain groups and an initiator system, wherein the initiator system comprises the following components: (a) at least one material capable of absorbing IR radiation, (b) at least one compound capable of producing radicals and (c) at least one hereto-substituted arylacetic acid co-initiator compound indicated by the following general structures:

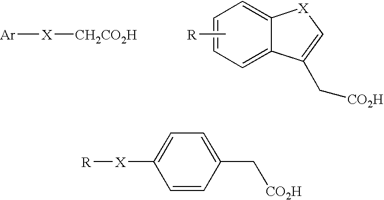

where X is either nitrogen, oxygen or sulfur, Ar is any substituted or unsubstituted aryl ring and R is any subconstituent.

### BACKGROUND OF THE INVENTION

1. Field of the Invention

The present invention relates to initiator systems and IR-sensitive compositions containing them which, inter alia, are extraordinarily suitable for the manufacture of printing plate precursors which can be imagewise exposed with IR-radiation.

Radiation-sensitive compositions usable particularly for high-performance printing plate precursors must fullfill high requirements.

The latest developments in the field of printing plate precursors deal with radiation-sensitive compositions which can be imagewise exposed by means of lasers or laser diodes. This type of exposure does not require films as intermediate information carriers since lasers can be controlled by computers.

High-performance lasers or laser diodes which are used in commercially available image-setters emit light in the wavelength ranges of between 800 to 850 nm and between 1060 and 1120 nm, respectively. Therefore, printing plate precursors, or initiator systems contained therein, which are to be imagewise exposed by means of such image-setters have to be sensitive in the near IR range. Such printing plate precursors can then basically be handled under daylight conditions which significantly facilitates their production and processing. There are two different possibilities of producing radiation-sensitive compositions for such printing plates.

For negative-working printing plates, radiation-sensitive compositions are used wherein after an imagewise exposure the exposed areas are cured. In the developing step only the unexposed areas are removed from the substrate. For positive-working printing plates, radiation-sensitive compositions are used whose exposed areas dissolve faster in a given developing agent than the non-exposed areas. This process is referred to as photosolubilization.

However, with regard to the radiation-sensitive compositions in positive systems, there is a certain dilemma since, for a high number of copies crosslinked polymers are needed. However, such polymers are insoluble in the solvents or solvent mixtures suitable for the plate coating so that non-crosslinked or only slightly crosslinked starting products are needed. The necessary crosslinking can then be achieved by preheating steps which can be carried out at various stages of the plate processing.

Printing plate, printed circuit board, and dry film resist precursor compositions generally comprise at least one IR-absorbing compound, at least one compound capable of producing free radicals, at least one co-initiator compound and at least one polymerizable component from the group consisting of unsaturated free radical polymerizable monomers, oligomers and polymers having ethylenic unsaturation.

IR-sensitive imaging compositions that rely solely on triazines or N-alkoxy pyridinium salts as free radical initiators for polymerization of unsaturated monomers are impracticably slow, necessitating the use of a co-initiator.

2. Brief Description of Related Developments

It is known from Hauck et al. U.S. Pat. No. 6,309,792, the entire disclosure of which is hereby incorporated herein by reference thereto, that the addition of certain polycarboxylic acid compounds as co-initiators to such IR-sensitive imaging compositions significantly improves their photo-reaction speed. There is a need to identify other materials that can serve as co-initiators to improve the reaction speed of such IR-sensitive imaging compositions.

It is also known to incorporate certain mono-carboxylic acid derivatives such as phenoxyacetic acid and thiophenoxyacetic acid and N-methylindole-3-acetic acid as co-initiators in UV-sensitive imaging compositions, in U.S. Pat. No. 4,366,228, and by Wzyszczynski et al. in Macromolecules 2000, 33, 1577-1582. However, such compositions lack IR-sensitivity. In U.S. Pat. No. 4,366,228, the mono-carboxylic acid is used as the sole initiator, in the absence of any triazine or N-alkoxypyridinium salt co-initiator. Also the monocarboxylic acid compositions are disclosed to be slower than compositions containing N-phenylglycine (NPG). The initiating chromophore in the Macromolecules reference compositions is 4-carboxybenzophenone.

It is also known to incorporate different classes of heteroarylacetic acid compounds in UV-curable silver halide photographic emulsion compositions, and reference is made to U.S. Pat. No. 6,054,260.

Radiation-sensitive compositions which show both a high degree of radiation sensitivity and a sufficiently long shelf-life when used in the manufacture of printing plate precursors are presently only known in connection with UV-absorbing dyes (EP-A-0 730 201). However, printing plate precursors using such compositions have to be manufactured and processed under darkroom conditions and cannot be imagewise exposed by means of the above-mentioned lasers or laser diodes. Particularly the fact that they cannot be processed in daylight limits their possibilities of application.

### SUMMARY OF THE INVENTION

It is an objective of the present invention to provide novel IR-sensitive imaging compositions, similar to those of U.S. Pat. No. 6,309,792, but containing co-initiator compounds other than polycarboxylic acid compounds.

It is another object of the present invention to provide IR-sensitive compositions which allow the manufacture of negative-working printing plate precursors having a long shelf-life, providing a continuously high number of copies and a high degree of resistance to developing chemicals, and which are additionally characterized by a high IR sensitivity and resolving power as well as processability in daylight, and to use such IR-sensitive compositions for preparing negative-working printing plate precursors.

These objects are achieved by an IR-sensitive composition comprising, in addition to a polymeric binder, a free radical polymerizable system consisting of at least one member selected from unsaturated free radical polymerizable monomers, oligomers which are free radical polymerizable, and polymers containing C═C bonds in the back bone and/or in the side chain groups, and an initiator system, wherein the initiator system comprises the following components:

(a) at least one material capable of absorbing IR radiation

(b) at least one compound capable of producing radicals and

(c) at least one hetero-substituted arylacetic acid co-initiator compound indicated by the following general structures:

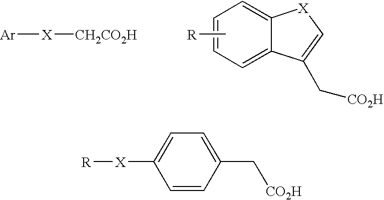

where X is either nitrogen, oxygen or sulfur, Ar is any substituted or unsubstituted aryl ring and R is any substituent.

### DETAILED DESCRIPTION OF THE PREFERRED EMBODIMENT(S)

Useful infrared absorbing materials (a) typically have a maximum absorption wavelength in the near infrared region of the electromagnetic spectrum, greater than about 750 nm; more particularly, their maximum absorption wavelength is in the range from about 800 to about 1200 nm.

Preferably the at least one compound (a) is selected from triarylamine dyes, thiazolium dyes, indolium dyes, oxazolium dyes, cyanine dyes, polyaniline dyes, polypyrrole dyes, polythiophene dyes and phthalocyanine pigments.

It is more preferred that component (a) is a cyanine dye of the formula (A)

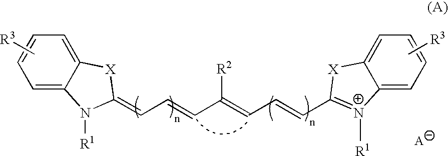

wherein:

each X independently represents S, O, NR or C(alkyl)₂; each R¹ independently is an alkyl group, an alkylsulfonate or an alkylammonium group;

R² represents hydrogen, halogen, SR, SO₂R, OR or NR₂; each R³ independently represents a hydrogen atom, an alkyl group, COOR, OR, SR, NR₂, a halogen atom or an optionally substituted benzofused ring;

A— represents an anion;

- - - represents an optional carbocyclic five- or six-membered ring;

each R independently represents hydrogen, an alkyl or aryl group;

each n independently is 0, 1, 2 or 3.

If R¹ is an alkylsulfonate group A— can be absent (formation of an inner salt); otherwise an alkali metal cation is necessary as counterion. If R¹ is an alkyl-ammonium group a second anion is necessary as counterion; this second anion may be the same as A— or a different one.

Compound (b) preferably is selected from polyhaloalkyl-substituted compounds and azinium compounds.

In the present free radical polymerizable system all three of the components (a), (b) and (c) interact to generate the initiating radical, i.e., the radical formed between component (a) and component (b) and the heteroaryl acetic acid. In order to achieve a high degree of radiation sensitivity, the presence of all three components is indispensable. It was found that completely radiation-insensitive compositions were obtained when component (b) was missing. The heteroaryl acetic acid is necessary to obtain the required thermal stability. If the heteroaryl acetic acid is replaced for example by compounds having a mercapto group or by ammonium borates the radiation sensitivity can be slightly decreased and the thermal stability of such compositions can be insufficient.

Basically all polymers or polymer mixtures known in the art can be used as polymeric binders, for example acrylic acid copolymers and methacrylic acid copolymers. Preferably, the polymers have a weight-average molecular weight in the range of 10,000 to 1,000,000 (determined by means of GPC). In view of possible problems occurring in connection with ink acceptance during the printing process, it is preferred that the used polymer has an acid number of >70 mg KOH/g, or, when polymer mixtures are used, that the arithmetic average of the individual acid numbers be >70 mg KOH/g. A polymer or polymer mixture with an acid number of >110 mg KOH/g is preferred; especially preferred is an acid number between 140 and 160 mg KOH/g. The content of the polymeric binder in the IR-sensitive composition preferably accounts for 30 to 60 wt.-%, more preferably 35 to 45 wt.-%, based on the total solids content of the IR-sensitive composition.

As unsaturated free radical polymerizable monomers or oligomers, use can be made of for example acrylic or methacrylic acid derivatives with one or more unsaturated groups, preferably esters of acrylic or methacrylic acid in the form of monomers, oligomers or prepolymers. They may be present in solid or liquid form, with solid and highly viscous forms being preferred. The compounds suitable as monomers include for instance trimethylol propane triacrylate and methacrylate, pentaerythritol triacrylate and methacrylate, dipentaerythritolmono hydroxy pentaacrylate and methacrylate, dipentaerythritol hexaacrylate and methacrylate, pentaerythritol tetraacrylate and methacrylate, ditrimethylolpropane tetracrylate and methacrylate, diethyleneglycol diacrylate and methacrylate, triethyleneglycol diacrylate and methacrylate or tetraethyleneglycol diacrylate and methacrylate. Suitable oligomers and/or prepolymers are urethane acrylates and methacrylates, epoxide acrylates and methacrylates, polyester acrylates and methacrylates, polyether acrylates and methacrylates or unsaturated polyester resins.

Besides monomers and oligomers, polymers having C═C bonds in the back bone and/or in the side chains can be used.

Examples thereof include: reaction products of maleic anhydride-olefin-copolymers and hydroxyalkyl(meth)acrylates, polyesters containing an allyl alcohol group, reaction products of polymeric polyalcohols and isocyanate (meth)acrylates, unsaturated polyesters and (meth)acrylate terminated polystyrenes, poly(meth)acrylics and polyethers.

The weight ratio of the free radical polymerizable monomers of oligomers is preferably 35 to 60 wt.-%, more preferably 45 to 55 wt.-%, based on the total solids content of the IR-sensitive composition.

The initiator system of the present invention comprises as an essential component a material capable of absorbing IR radiation. This IR absorber is preferably selected from triarylamine dyes, thiazolium dyes, indolium dyes, oxazolium dyes, cyanine dyes, polyaniline dyes, polypyrrole dyes, polythiophene dyes, and phthalocyanine pigments. More preferred are IR dyes of the formula (A)

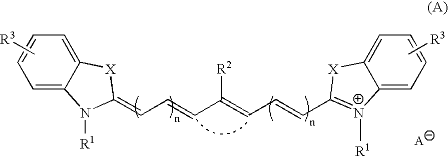

wherein:

X is preferably a C(alkyl)₂ group.

R¹ is preferably an alkyl group with 1 to 4 carbon atoms,

R² is preferably SR.

R³ is preferably a hydrogen atom.

R is preferably an alkyl or aryl group; especially preferred is a phenyl group.

The broken line preferably represents the rest of a ring with 5 or 6 carbon atoms.

The counterion A— is preferably a chloride ion or a tosylate anion or an ammonium ion.

Especially preferred are IR dyes with a symmetrical formula (A). Examples of such especially preferred dyes include:

2-[2-[2-phenylsulfonyl-3-[2-(1,3-dihydro-1,3,3-trimethyl-2H-indol-2-ylidene)-ethylidene]-1-cyclohexen-1-yl]-ethenyl]-1,3,3-trimethyl-3H-indolium chloride,

2-[2-[2-thiophenyl-3-[2-(1,3-dihydro-1,3,3-trimethyl-2H-indol-2-ylidene)-ethylidene]-1-cyclohexen-1-yl]ethenyl]-1,3,3-trimethyl-3H-indolium chloride,

2-[2-[2-thiophenyl-3-[2-(1,3-dihydro-1,3,3-trimethyl-2H-indol-2-ylidene)-ethylidene]-1-cyclopenten-1-yl]-ethenyl]-1,3,3-trimethyl-3H-indolium tosylate,

2-[2-[2-chloro-3-[2-ethyl-(3H-benzthiazole-2-ylidene)-ethylidene]-1-cyclohexen-1-yl]-ethenyl]-3-ethyl-benzthiazolium tosylate and

2-[2-[2-chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indolium tosylate.

Also useful IR absorbers for the compositions of the present invention are the following compounds:

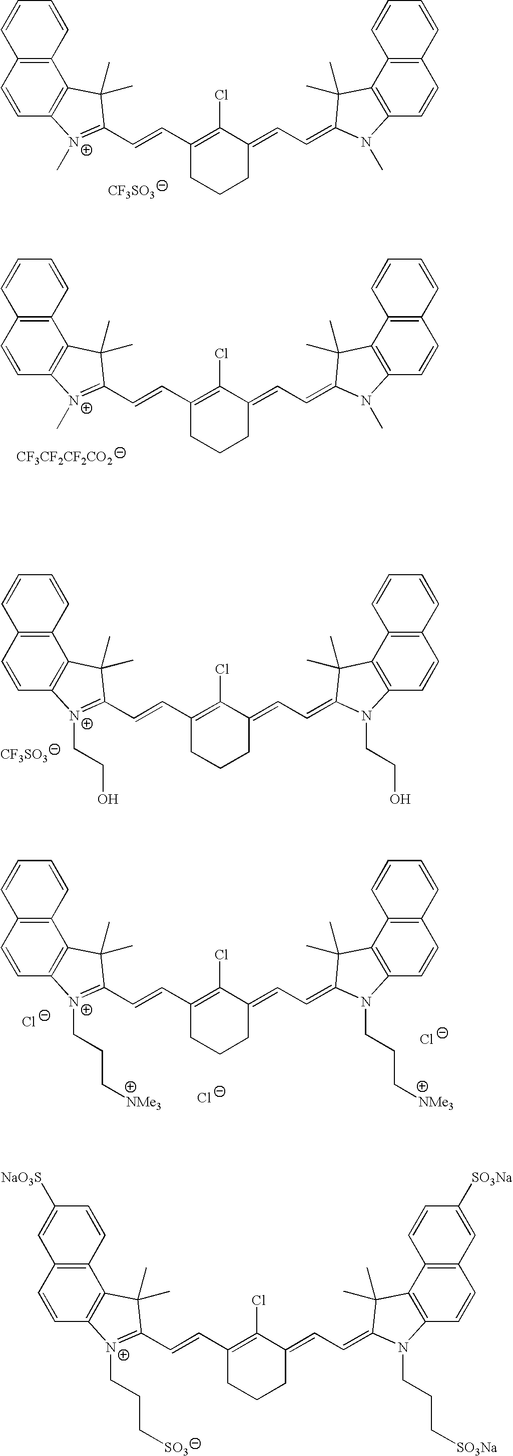

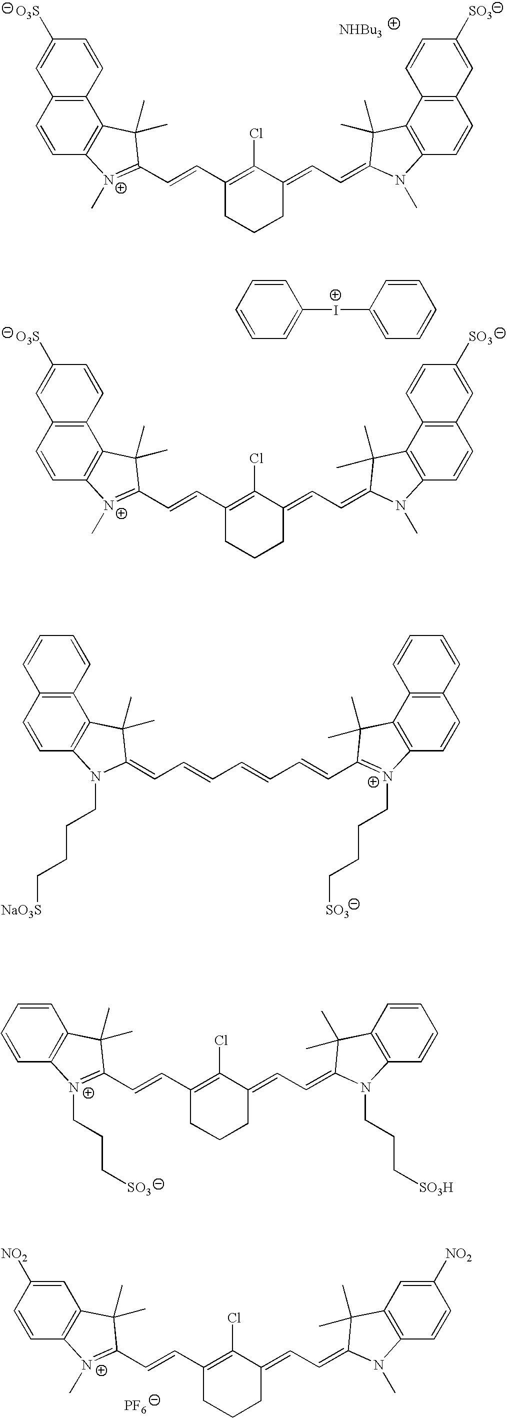

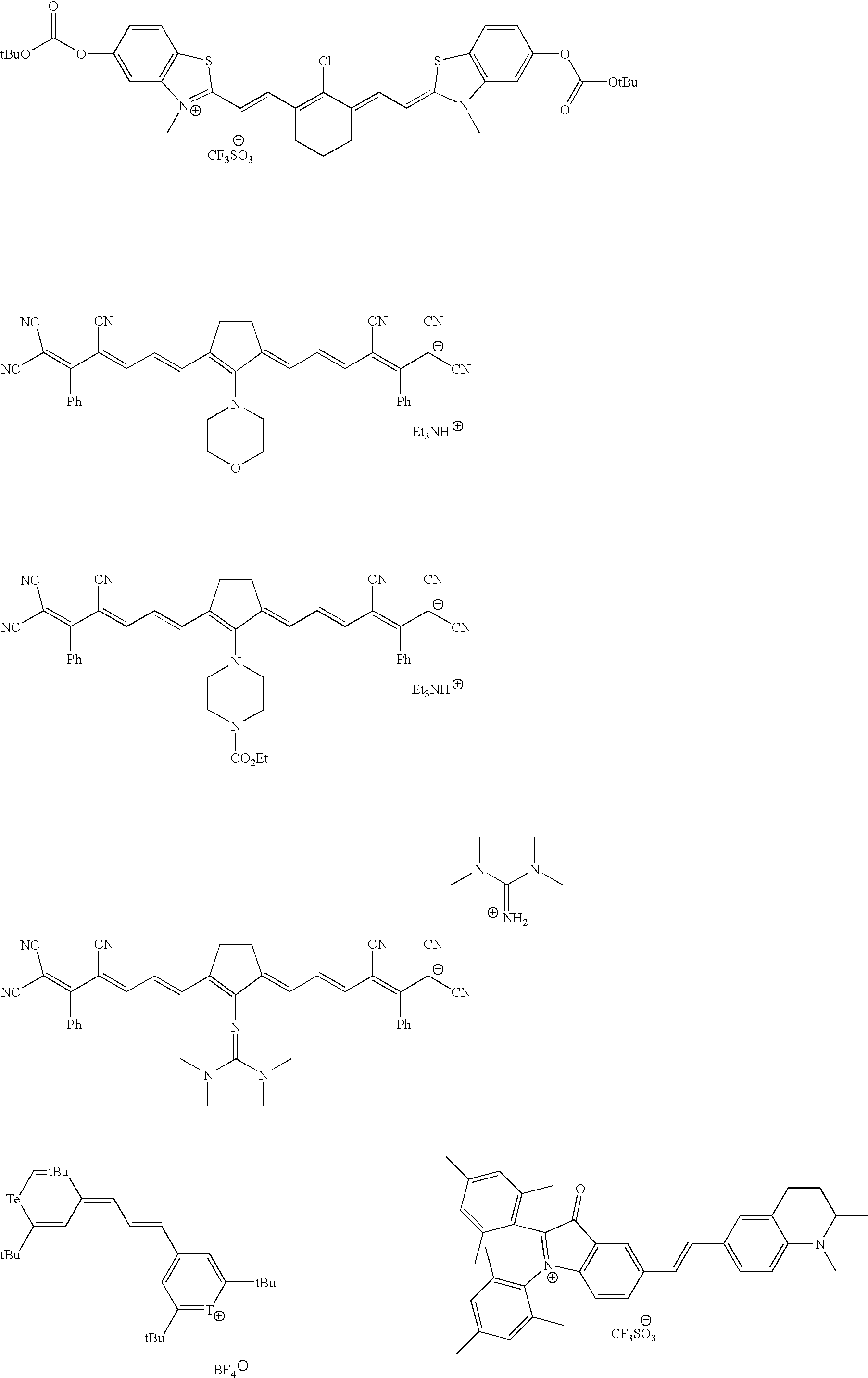

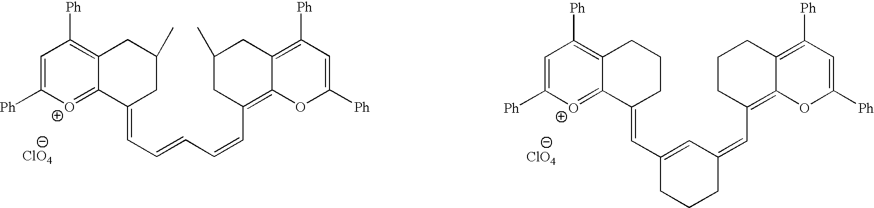

The IR absorber (a) is preferably present in the IR-sensitive composition in an amount of from 0.05 to 20 wt.-%, based on the total solids content of the IR-sensitive composition; especially preferred is an amount of from 0.5 to 8 wt.-%.

Another essential component of the initiator system is the compound (b) capable of producing radicals. Preferably this compound is selected from polyhaloalkyl-substituted compounds, and azinium compounds. Especially preferred are polyhaloalkyl-substituted compounds; these are compounds which comprise either one polyhalogenerated or several monohalogenated alkyl substituents. The halogenated alkyl group preferably has 1 to 3 carbon atoms; especially preferred is a halogenated methyl group.

The absorption properties of the polyhaloalkyl-substituted compound fundamentally determine the daylight stability of the IR-sensitive composition. Compounds having a UV/VIS absorption maximum of >330 nm result in compositions which can no longer be completely developed after the printing plate has been kept in daylight for 6 to 8 minutes and then preheated. As a principle, such compositions can be imagewise exposed not only with IR but also with UV radiation. If a high degree of daylight stability is desired, polyhaloalkyl-substituted compounds are preferred which do not have a UV/VIS absorption maximum at >330 nm.

The azinium compounds include an azinium nucleus, such as a monoazinium or diazinium nucleus. Suitable such compounds are disclosed in GB 2,083,832, the disclosure of which is incorporated herein by reference. The azinium nucleus can be fused by carbocyclic aromatic nucleus, i.e., can be benzo- or naptho-condensed. In other words, the azinium nuclei include quinolinium, isoquinolinium, benzodiazinium, and naphthodiazinium nuclei the latter two being benzo-fused diazinium compunds. To achieve the highest attainable activation efficiencies per unit of weight it is preferred to employ monocyclic azinium nuclei such as the pyridinium nucleus.

A quaternizing substituent of a nitrogen atom in the radical producing compound (b), such as the azinium ring, is capable of being released as a free radical upon electron transfer from the photosensitizer to the compound (b), such as the azinium compound. In one preferred form the quaternizing substituent is an oxy substituent. The oxy substituent (—O—R) which quaternizes a ring nitrogen atom of the azinium nucleus can be selected from among a variety of synthetically convenient oxy substituents. The moiety R can, for example, be an alkyl radical, which can be substituted; for example aralkyl and sulfoalkyl groups are contemplated. Most preferred oxy substitutents (—O—R) contain 1 or 2 carbon atoms.

Examples of especially suitable compounds (b) for the compositions of the present invention include:

N-methoxy-4-phenyl-pyridinium tetrafluoroborate, tribromomethylphenylsulfone, 1,2,3,4-tetrabromo-n-butane, 2-(4-methoxyphenyl)4,6-bis(trichloromethyl)-s-triazine, 2-(4-chlorophenyl)-4,6-bis-(trichloromethyl)-s-triazine, 2-phenyl)-4,6-bis(trichloromethyl)-s-triazine, 2,4,6-tri-(trichloromethyl)-s-triazine, 2,4,6-tri-(tribromomethyl)-s-triazine, 2-hydroxytetradecyloxyphenyl phenyliodonium hexafluoroantimonate, and 2-methoxy-4-phenylaminobenzene diazonium hexafluorophosphate.

Furthermore, the following compounds are useful as initiators (b) in the compositions of the present invention:

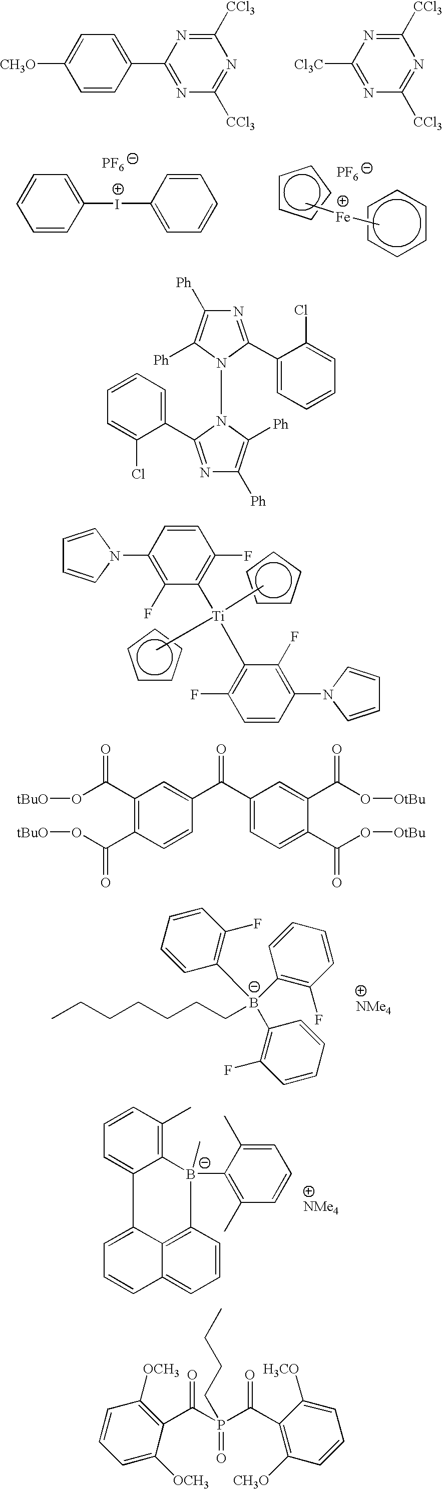

Compound (b) is preferably present in the IR-sensitive composition in an amount of from 2 to 15 wt.-%, based on the total solids content of the IR-sensitive composition; especially preferred is an amount of from 4 to 7 wt.-%.

The novel co-initiator compound (c) of the present IR-absorbing imaging compositions is a hetero-substituted aryl acetic acid having a struture indicated by one of the following:

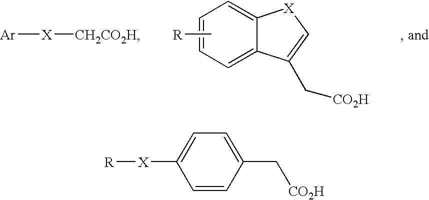

where X is either nitrogen, oxygen or sulfur, Ar is any substituted or unsubstituted aryl ring and R is any substituent.

Preferred mono acetic acids include:

Phenoxyacetic acid, (Phenylthio) acetic acid, N-methylindole-3-acetic acid, (2-methoxyphenoxy) acetic acid, (3,4-dimethoxyphenylthio) acetic acid, and 4-(dimethylamino) phenylacetic acid.

The IR-sensitive composition may furthermore comprise dyes for improving the contrast of the image. Suitable dyes are those that dissolve well in the solvent or solvent mixture used for coating or are easily introduced in the disperse form of a pigment. Suitable contrast dyes include inter alia rhodamine dyes, triarylmethane dyes, anthraquinone pigments and phthalocyanine dyes and/or pigments. The dyes are preferably present in the IR-sensitive composition in an amount of from 1 to 15 wt.-%, especially preferred in an amount of from 2 to 7 wt.-%

The IR-sensitive compositions of the present invention may furthermore comprise a plasticizer. Suitable plasticizers include, inter alia, dibutyl phthalate, triaryl phosphate and dioctyl phthalate. If a plasticizer is used, it is preferably present in an amount in the range of 0.25 to 2 wt.-%.

The IR-sensitive compositions of the present invention are preferably usable for the manufacture of printing plate precursors. In addition, however, they may be used in recording materials for creating images on suitable carriers and receiving sheets, for creating reliefs that may serve as printing plates, screens and the like, as radiation-curable varnishes for surface protection and for the formulation of radiation-curable printing inks.

For the manufacture of offset printing plate precursors, conventional carriers can be used; the use of an aluminum carrier is especially preferred. When an aluminum carrier is used it is preferred that it is first roughened by brushing in a dry state, brushing with an abrasive suspension or electrochemically, e.g. in an hydrochloric acid electrolyte; the roughened plates, which were optionally anodically oxidized in sulfuric or phosphoric acid, are then subjected to a hydrophilizing after treatment, preferably in an aqueous solution of polyvinylphosphonic acid or phosphoric acid. The details of the above-mentioned substrate pretreatment are well-known to the person skilled in the art.

The dried plates are then coated with the inventive IR-sensitive compositions from organic solvents or solvent mixtures such that dry layer weights of preferably from 0.5 to 4 g/m², more preferably 0.8 to 3 g/m², are obtained.

On top of the IR-sensitive layer, an oxygen-impermeable layer is applied as it is known in the art, e.g. a layer having little or no permeability to oxygen, such as a layer of polyvinyl alcohol, polyvinyl alcohol/polyvinyl acetate copolymers, polyvinyl pyrrolidone, polyvinyl pyrrolidone/polyvinyl acetate copolymers, polyvinyl methylether, polyacrylic acid and gelatin. The dry layer weight of the oxygen-impermeable layer is preferably 0.1 to 4 g/m², more preferably 0.3 to 2 g/m². This overcoat is not only useful as oxygen barrier but also protects the plate against ablation during exposure to IR radiation.

The thus obtained printing plate precursors are exposed with semiconductor lasers or laser diodes which emit in the range of 800 to 1,100 nm. Such a laser beam can be digitally controlled via a computer, i.e. it can be turned on or off so that an imagewise exposure of the plates can be effected via stored digitalized information in the computer. Therefore, the IR-sensitive compositions of the present invention are suitable for creating what is referred to as computer-to-plate (ctp) printing plates.

After the printing plate precursor has been imagewise exposed, it is optionally briefly heated to a temperature of 85 to 135° C., in order to effect complete curing of the exposed areas. Depending on the temperature applied, this only takes 20 to 100 seconds.

Then the plates are developed as known to the person skilled in the art. The developed plates are usually treated with a preservative (“gumming”). The preservatives are aqueous solutions of hydrophilic polymers, wetting agents and other additives.

The following examples serve to provide a more detailed explanation of the invention.

### EXAMPLES 1-5

Five coating formulations were prepared as detailed in Table 1. The solutions were applied to electrochemically grained and anodized aluminum substrates and dried to give a coating weight of 2 g/m².

TABLE 1
Composition of Examples 1-5
(formulations in parts by weight).

| | Example | Example | Example | Example | Example |
|---|---|---|---|---|---|
| Component | 1 | 2 | 3 | 4 | 5 |
| Reaction product of Desmodur | 3.56 | 3.56 | 3.56 | 3.56 | 3.56 |
| N100⁶ with hydroxyethyl | | | | | |
| acrylate and pentaerythritol | | | | | |
| triacrylate | | | | | |
| Joncryl 683¹ | 1.61 | 1.61 | 1.61 | 1.61 | 1.61 |
| Jagotex MA 2814² | 1.61 | 1.61 | 1.61 | 1.61 | 1.61 |
| Sartomer 355³ | 0.74 | 0.74 | 0.74 | 0.74 | 0.74 |
| 2-(4-methoxyphenyl)-4,6- | 0.39 | 0.39 | 0.39 | 0.39 | 0.39 |
| bis (trichloromethyl-s- | | | | | |
| triazine | | | | | |
| Phenoxyacetic acid | 0.21 | — | — | — | — |
| (2-Methoxyphenoxy) acetic | — | 0.21 | — | — | — |
| acid | | | | | |
| (3,4-Dimethoxyphenylthio) | — | — | 0.21 | — | — |
| acetic acid | | | | | |
| N-phenylglycine | — | — | — | 0.21 | — |
| Indole-3-acetic acid | — | — | — | — | 0.21 |
| IR dye⁴ | 0.13 | 0.13 | 0.13 | 0.13 | 0.13 |
| Crystal Violet | 0.10 | 0.10 | 0.10 | 0.10 | 0.10 |
| Byk 307⁵ | 0.02 | 0.02 | 0.02 | 0.02 | 0.02 |
| 2-Butanone | 13.74 | 13.74 | 13.74 | 13.74 | 13.74 |
| Toluene | 22.91 | 22.91 | 22.91 | 22.91 | 22.91 |
| 1-Methoxy-2-propanol | 54.98 | 54.98 | 54.98 | 54.98 | 54.98 |

¹Joncryl 683 is an acrylic acid copolymer available from S C Johnson & Son, Inc.
²Jagotex MA 2814 is an acrylic copolymer available from Ernst Jäger GmbH & Co.
³Sartomer 355 is a multifunctional acrylic monomer available from Sartomer Co., Inc.
⁴The IR dye is 2-[2-[2-phenylthio-3-[(1,3-dihydro-1,3,3-trimethyl-2H-indol-2-ylidene) ethylidene]-1-cyclohexen-1-yl]ethenyl]-1,3,3-trimethyl-3H-indolium chloride.
⁵Byk 307 is a modified polysiloxane available from Byk Chemie.
⁶Desmodur N100 is an aliphatic polyisocyanate resin based upon hexamethylene diisocyanate, from Bayer Corporation, Milford, CT.

Each of the resulting coatings was then over-coated with a solution of 5.26 parts polyvinyl alcohol and 0.93 parts of polyvinylimidazole in 3.94 parts of isopropanol and 89.97 parts of water and dried to a final coating weight of 2 g/m2.

Samples of coatings for Examples 1-3 were imaged on a Creo 3230 Trendsetter at a power setting of 2 W from 20 to 120 mJ/cm². Example 4 was imaged on a Creo Trendsetter 3244x at 4 W from 25 to 154 mJ/cm². Example 5 was imaged on a Creo Trendsetter 3244x at 5 W from 52 to 500 mJ/cm². Example 1-5 plates were then processed with 980 developer (from Kodak Polychrome Graphics) through a Technigraph processor equipped with a pre-development heating unit adjusted to bring the plate surface temperature to 125° C. Table 2 compares the maximum processed optical densities of the five plates in relation to the exposure dose required to obtain the observed result.

TABLE 2
Photosensitivity comparisons.

| | Exposure | Maximum Processed |
|---|---|---|
| Plate | (mJ/cm²) | Density |
| Example 1 | 84 | 0.92 |
| Example 2 | 93 | 0.84 |
| Example 3 | 88 | 0.79 |
| Example 4 | 137 | 0.80 |
| Example 5 | 119 | 1.05 |

The results summarized in Table 2 show that the maximum optical densities of the processed coatings of the present invention and the minimum exposure necessary to reach the maximum processed density.

A sample of each plate was also incubated under accelerated aging conditions of 5 days at 38° C. and 80% relative humidity before being imaged and processed as above. The reflective density of each plate at the minimum exposure necessary to achieve maximum processed density was then measured and compared with the corresponding densities of the fresh plates to determine the percent loss in coating density. The results summarized in Table 3 show that the coatings of the present invention have good shelf life stability with respect to coating density loss upon aging.

TABLE 3
Effect of accelerated aging.

| | Exposure | Percent Coating |
|---|---|---|
| Plate | (mJ/cm²) | Density Loss |
| Example 1 | 269 | 24% |
| Example 2 | 112 | 19% |
| Example 3 | 111 | 15% |
| Example 4 | 275 | 17% |
| Example 5 | 348 | 14% |

### EXAMPLE 6

The base coat formulation for example 6 was prepared as described in example 1 except that in place of phenoxyacetic acid, 4-(dimethylamino)phenylacetic acid was substituted. The base coat was applied and the overcoat prepared and applied as described in example 1. Plates were imaged and processed as described in example 1. A maximum processed density of 0.55 was achieved at a minimum exposure energy of ˜130 mJ/cm² (the unprocessed density for this coating was 0.83, while for examples 1-5 the unprocessed density was about 1.0).

### COMPARATIVE EXAMPLE 7

The coating formulation for comparative example 6 was prepared as detailed in example 1 except that phenoxyacetic acid was omitted. The solutions were applied to electrochemically grained and anodized aluminum substrates and dried to give a coating weight of 2 g/m².

The resulting coatings was then over-coated with a solution of 5.26 parts polyvinyl alcohol and 0.93 parts of polyvinylimidazole in 3.94 parts of isopropanol and 89.97 parts of water and dried to a final coating weight of 2 g/m².

A sample of coating was imaged on a Creo 3230 Trendsetter at a power setting of 10 W from 100 to 800 mJ/cm². The plate was then processed with 980 developer (from Kodak Polychrome Graphics) through a Technigraph processor equipped with a pre-development heating unit adjusted to bring the plate surface temperature to 125° C. The minimum exposure energy necessary to achieve maximum processed density was ˜300 mJ/cm² with a processed density of 0.78. This example shows that the hetero-substituted arylacetic acid coinitiators of the present invention substantially improve the photo speed over that which would otherwise be obtained in their absence.

It should be understood that the foregoing description is only illustrative of the invention. Various alternatives and modifications can be devised by those skilled in the art without departing from the invention. Accordingly, the present invention is intended to embrace all such alternatives, modifications and variances which fall within the scope of the appended claims.

What is claimed is:

1. An IR-sensitive composition comprising an initiator system comprising the following components:
(a) at least one material capable of absorbing IR radiation;
(b) at least one compound capable of producing radicals, and
(c) at least one hetero-substituted arylacetic acid co-initiator compound selected from the group consisting of the following general structures: 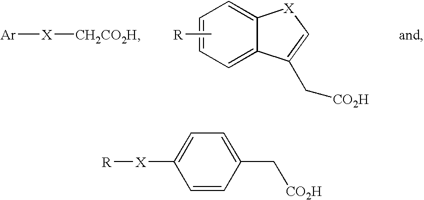
where X is either nitrogen, oxygen or sulfur, Ar is any substituted or unsubstituted aryl ring and R is any subconstituent.

2. A composition according to claim 1 in which the hetero-substituted arylacetic acid co-initiator is selected from the group consisting of Phenoxyacetic acid, (Phenylthio) acetic acid, N-methylindole-3-acetic acid, (2-methoxyphenoxy) acetic acid, (3,4-dimethoxyphenylthio) acetic acid, and 4-(dimethylamino)phenylacetic acid.

3. A composition according to claim 1 wherein the material capable of absorbing IR radiation is selected from the group consisting of triarylamine dyes, thiazolium dyes, indolium dyes, oxazolium dyes, cyanine dyes, polyaniline dyes, polypyrrole dyes, polythiophene dyes and phthalocyanine pigments.

4. A composition according to claim 2 wherein the material capable of absorbing IR-radiation is a cyanine dye of the formula (A) 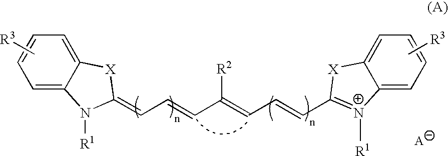
wherein
each X independently represent S, O, NR or C(alkyl)₂;
each R¹ independently is an alkyl group, an alkylsulfonate or an alkylammonium group;
R² represents a hydrogen, halogen, SR, SO₂R, OR or NR₂;
Each R³ independently represents a hydrogen atom, an alkyl group, COOR, OR, SR, NR₂, a halogen atom or an optionally substituted benzofused ring;
A— represents an anion;
- - - represents an optional carbocyclic five- or six-membered ring;
each R independently represents hydrogen, an alkyl or aryl group;
each n independently is 0, 1, 2 or 3.

5. A composition according to claim 1 wherein the compound capable of producing radicals is selected from the group consisting of polyhaloalkyl-substituted compounds and azinium compounds.

6. A composition according to claim 1, wherein the material capable of absorbing IR radiation is selected from the group consisting of
2-[2-[2-thiophenyl-3-[2-(1,3-dihydro-1,3,3-trimethyl-2H-indol-2-ylidene)-ethylidene]-1-cyclopenten-1-yl]-ethenyl]-1,3,3-trimethyl-3H-indolium tosylate,
2-[2-[2-phenylsulfonyl-3-[2-(1,3-dihydro-1,3,3-timethyl-2H-indol-2-ylidene)-ethylidene]-1-cyclohexen-1-yl]-ethenyl]-1,3,3-trimethyl-3H-indolium chloride,
2-[2-[2-thiophenyl-3-[2-(1,3-dihydro-1,3,3-trimethyl-2H-indol-2-ylidene)-ethylidene]-1-cyclohexen-1-yl]-ethenyl]-1,3,3-trimethyl-3H-indolium chloride,
2-[2-[2-chloro-3-[2-(1,3-dihydro-1,3,3-trimethyl-2H-indol-2-ylidene)-ethylidene]-1-cyclohexen-1-yl]-ethenyl]-1,3,3-trimethyl-3H-indoliumtosylate and
2-[2-[2-chloro-3-[2-ethyl-(3H-benzthiazol-2-ylidene)-ethylidene]-1-cyclohexen-1-yl]-ethenyl]-3-ethyl-benzthiazoliumtosylate.

7. A composition according to claim 1 wherein the compound capable of producing radicals is selected from the group consisting of
N-methoxy-4-phenylpyridinium tetrafluoroborate, 2-hydroxytetradecyloxyphenyl phenyliodonium hexafluoroantimonate, 2-methoxy-4-phenylaminobenzene diazonium hexafluorophosphate, 2-phenyl-4,6-bis-(trichloromethyl)-s-triazine, 2-(4-methoxyphenyl)-4,6-bis(trichloromethyl)-s-triazine, tribromomethylphenylsulfone, 2,4,6-tri(trichloromethyl)-s-triazine and 1,2,3,4-tetrabromo-n-butane.

8. IR-sensitive composition according to claim 1 further comprising a polymeric binder and at least one component selected from the group consisting of unsaturated free radical polymerizable monomers, oligomers which are free radical polymerizable and polymers having C═C bonds in the back bone and/or in the side chain groups.

9. Composition according to claim 8 additionally comprising at least one dye for increasing the contrast of the image.

10. Printing plate precursor comprising coating with a composition according to claim 8 and an oxygen-impermeable overcoating.

11. A method for providing an image, comprising:
(a) coating an optionally pretreated substrate with an IR-sensitive composition as defined in claim 8 and subsequently coating with an oxygen-impermeable overcoating.
(b) imagewise exposing the printing plate precursor obtained in step (a) to IR radiation
(c) optionally subjecting the treated precursor of step (b) to a heating step and
(d) subsequently developing the precursor with an aqueous developer to obtain a printable lithographic printing plate.
